(19) United States
(12) Patent Application Publication
(10) Pub. No.: US 2026/0249172 A1
(43) Pub. Date: Aug. 27, 2026

(54) MULTIFUNCTIONAL INTELLIGENT GAME CONTROLLER WITH HEAT DISSIPATION AND WIRELESS CHARGING

(71) Applicant: Tuoman International Limited, HONG KONG (CN)

(72) Inventor: Yunfang Xiong, HONG KONG (CN)

(21) Appl. No.: 19/650,289

(22) Filed: Apr. 16, 2026

(30) Foreign Application Priority Data
Apr. 1, 2026 (CN) 2026204303088

(51) Int. Cl. A63F 13/23; A63F 13/24; A63F 13/92; G06F 1/16; G06F 1/20; G06F 1/3215; H02J 50/00; H02J 50/10; H05K 7/20; H10N 10/80

(52) U.S. Cl. CPC A63F 13/23; A63F 13/24; A63F 13/92; G06F 1/1607; G06F 1/1656; G06F 1/206; G06F 1/3215; H02J 50/005; H02J 50/10; H05K 7/20145; H05K 7/20154; H10N 10/80

(57) ABSTRACT

A multi-functional intelligent game controller with heat dissipation and wireless charging is provided. The grip portion is movable relative to the main body portion to fit different mobile phones. A guide hole, guide post and elastic member ensure stable sliding and automatic clamping. A heat insulation gap between the main body and grip blocks heat transfer and improves grip comfort. The device integrates wireless charging, thermoelectric cooling and heat dissipation. A temperature sensor and microcontroller adjust cooling power intelligently. A power management chip supports external power priority and battery charging switching. It ensures stable performance in high-power gaming and optimizes user experience.

### TECHNICAL FIELD

The present discloses relates to the technical field of electronic products, and in particular to a multi-functional intelligent game controller with heat dissipation and wireless charging.

### BACKGROUND ART

With continuous improvement in the graphics and performance of mobile games, mobile devices exhibit a significant increase in power consumption and heat generation during gaming, leading to issues such as insufficient battery life, processor throttling due to high temperatures, lagging, and reduced frame rates, which severely degrade user experience.

Although single-function products such as wireless chargers or mobile phone radiators exist in the prior art, there is a lack of an integrated solution that organically combines a game controller, wireless charging, and active heat dissipation.

Such products cannot simultaneously resolve battery life and overheating problems during gaming.

Moreover, most clamping structures adopt a fixed-size design, making it difficult to adapt to mobile phones of different sizes.

The user’s grip area is easily affected by heat from the mobile phone, resulting in poor user experience.

Therefore, a multi-functional intelligent game controller with heat dissipation and wireless charging is proposed to address the above problems.

### SUMMARY

### Technical Problems to Be Solved

In view of the shortcomings of the prior art, the present discloses provides a multi-functional intelligent game controller with heat dissipation and wireless charging, which solves the problems of single function, fixed clamping size, and heat conduction to the grip in existing products.

### Technical Solution

To achieve the above objective, the present discloses adopts the following specific technical solutions:

A multi-functional intelligent game controller with heat dissipation and wireless charging, comprising:

a controller body having a clamping structure for holding a mobile terminal;

a wireless charging module disposed inside the controller body and configured to wirelessly charge the mobile terminal;

a thermoelectric cooling module disposed inside the controller body and configured to cool the mobile terminal;

a heat dissipation module disposed on one side of the thermoelectric cooling module and configured to dissipate heat generated by the thermoelectric cooling module.

Further, the clamping structure comprises a main body portion and a grip portion movably connected to at least one end of the main body portion, wherein the grip portion is movable relative to the main body portion to adjust the clamping width.

Further, at least one side of the main body portion is extended with a connecting plate, and the connecting plate is formed with a guide hole extending along its length; the grip portion is internally provided with a guide post slidably engaged with the guide hole;

the main body portion is internally provided with a first connecting portion, and the grip portion is internally provided with a second connecting portion; the connecting plate is internally provided with an elastic member, two ends of the elastic member being respectively connected to the first connecting portion and the second connecting portion to provide a restoring force to the grip portion toward the main body portion;

the grip portion is internally provided with a battery, the main body portion is internally provided with a circuit board, and the battery is electrically connected to the circuit board.

Further, the controller further comprises a temperature detection unit and a control unit, wherein the temperature detection unit is configured to detect temperature, and the control unit is electrically connected to the wireless charging module, the thermoelectric cooling module, and the temperature detection unit, respectively;

the control unit is configured to adjust the operating power of the thermoelectric cooling module according to a detection result of the temperature detection unit;

the temperature detection unit and the control unit are integrally disposed on the circuit board.

Further, a top portion of the main body portion is provided with a limiting flange along an edge thereof, and one side of the limiting flange is provided with a first flexible pad; the grip portion comprises a front shell and a bottom shell fastened to each other, a top portion of the front shell is formed with an L-shaped limiting arm, and an inner side of the limiting arm and the top portion of the front shell are jointly provided with a second flexible pad; the limiting arm and the limiting flange together define a U-shaped limiting space for accommodating the mobile terminal.

Further, a top surface of the main body portion is higher than a top surface of the front shell, such that a back surface of the mobile terminal is attached to the top surface of the main body portion and maintains a gap with the top surface of the front shell after assembly;

the second flexible pad is further provided with a supporting portion at a position corresponding to an inner side of the limiting arm, and a height of the supporting portion matches a protruding height of the top surface of the main body portion to support the mobile terminal.

Further, the wireless charging module comprises a wireless charging coil disposed inside the main body portion and a charging control circuit electrically connected to the wireless charging coil;

the thermoelectric cooling module comprises a thermoelectric cooling chip disposed inside the main body portion, the thermoelectric cooling chip having opposite cooling and heating surfaces, wherein the cooling surface is disposed toward the mobile terminal, and the heating surface is thermally connected to the heat dissipation module.

Further, the main body portion comprises an upper shell and a lower shell, a central bottom portion of the lower shell is formed with an air inlet, and front and rear sides of the bottom portion of the lower shell are respectively formed with air outlets;

a plurality of magnets are disposed inside the upper shell, and the plurality of magnets are arranged at intervals around the wireless charging coil and closely attached to an inner wall of the upper shell;

the circuit board is formed with an escape hole, and the cooling surface of the thermoelectric cooling chip passes through the escape hole and is attached to a bottom portion of the wireless charging coil.

Further, the heat dissipation module comprises a heat conduction bracket and a fan, a middle portion of the heat conduction bracket is attached to the heating surface of the thermoelectric cooling chip, two ends of the heat conduction bracket extend downward and are provided with heat dissipation fin groups, and the two heat dissipation fin groups respectively extend to the two air outlets; the fan is disposed between the middle portion of the heat conduction bracket and the air inlet.

Further, a charging interface, a switch button, and an indicator light are integrated on the circuit board; the circuit board is further provided with a light shield cooperating with the indicator light, and one end of the light shield is provided with a light guide post;

the upper shell is formed with through holes at corresponding positions for exposing the charging interface, the switch button, and the light guide post.

### Beneficial Effects

Compared with the prior art, the present discloses provides a multi-functional intelligent game controller with heat dissipation and wireless charging, having the following beneficial effects:

The present discloses adapts to mobile phones of different sizes via the grip portion movable relative to the main body portion; the guide hole and the guide post ensure stable extension and retraction, and the elastic member achieves automatic reset and clamping, enabling convenient operation.

The top surface of the main body portion is higher than the top surface of the grip portion to form a heat insulation gap.

Cooperating with the limiting flange, the L-shaped limiting arm, and the supporting portion on the second flexible pad, the controller stably clamps the mobile phone while effectively blocking heat conduction to the grip portion, improving grip comfort.

The controller integrates wireless charging, thermoelectric cooling, and heat dissipation functions.

A temperature sensor cooperates with a microcontroller to automatically adjust the power of the thermoelectric cooling chip according to temperature, realizing on-demand cooling.

Combined with a power management chip, the controller intelligently switches between external power priority supply and battery charging, ensuring stable operation in high-power scenarios while maintaining portability, thereby comprehensively optimizing the user’s gaming experience.

### BRIEF DESCRIPTION OF THE DRAWINGS

FIG. 1 is a schematic structural diagram of the grip portion in a retracted state relative to the main body portion according to the present discloses.

FIG. 2 is another schematic structural diagram of the grip portion in a retracted state relative to the main body portion according to the present discloses.

FIG. 3 is a further schematic structural diagram of the grip portion in a retracted state relative to the main body portion according to the present discloses.

FIG. 4 is a schematic structural diagram of the grip portion in an extended state relative to the main body portion according to the present discloses.

FIG. 5 is another schematic structural diagram of the grip portion in an extended state relative to the main body portion according to the present discloses.

FIG. 6 is a structural view of the elastic member according to the present discloses.

FIG. 7 is a structural view of the heat dissipation module according to the present discloses.

FIG. 8 is an exploded view of the controller body according to the present discloses.

FIG. 9 is a structural view of the thermoelectric cooling chip according to the present discloses.

FIG. 10 is another structural view of the thermoelectric cooling chip according to the present discloses.

### DETAILED DESCRIPTION OF THE EMBODIMENTS

The technical solutions in the embodiments of the present discloses will be clearly and completely described below with reference to the accompanying drawings in the embodiments of the present discloses.

It is obvious that the described embodiments are only part of the embodiments of the present discloses, not all of them.

Based on the embodiments of the present discloses, all other embodiments obtained by those skilled in the art without creative efforts shall fall within the protection scope of the present discloses.

### Embodiment

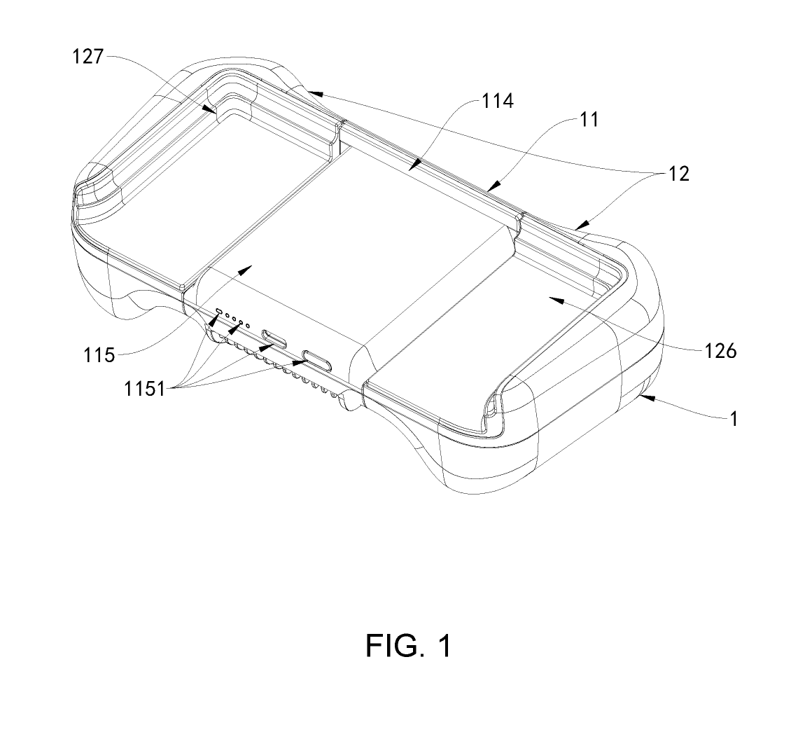

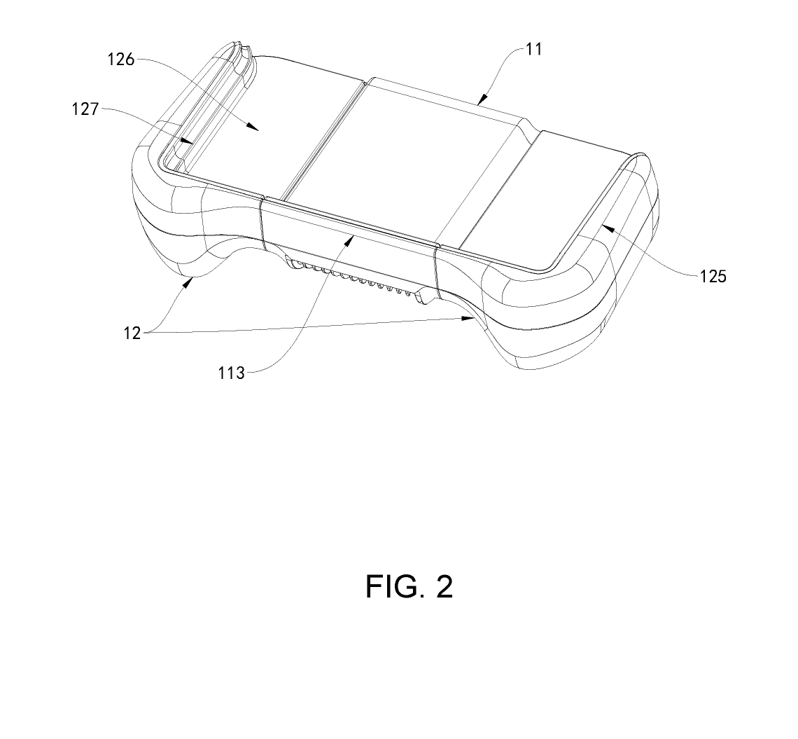

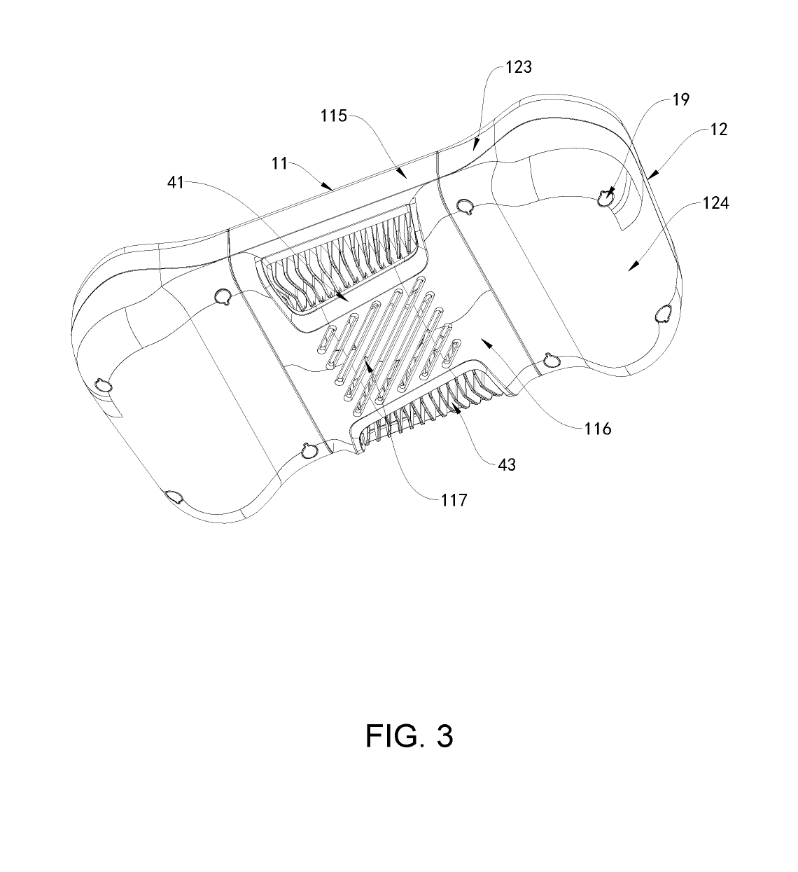

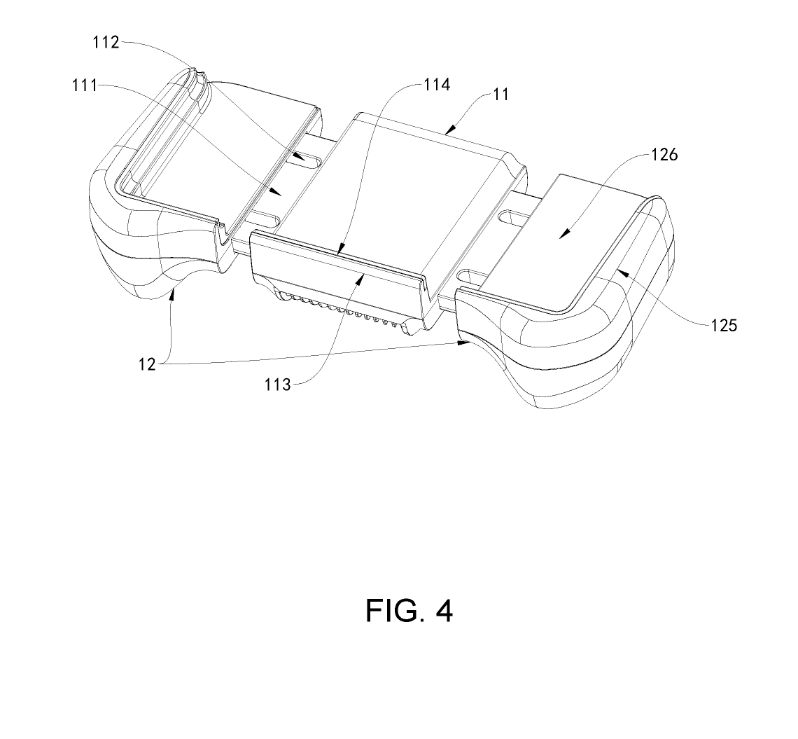

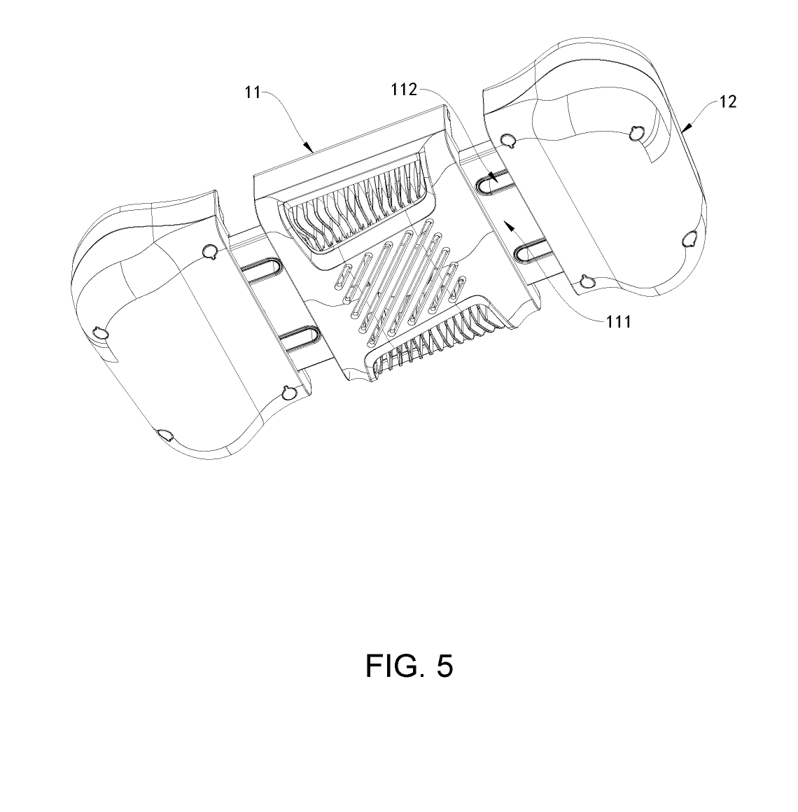

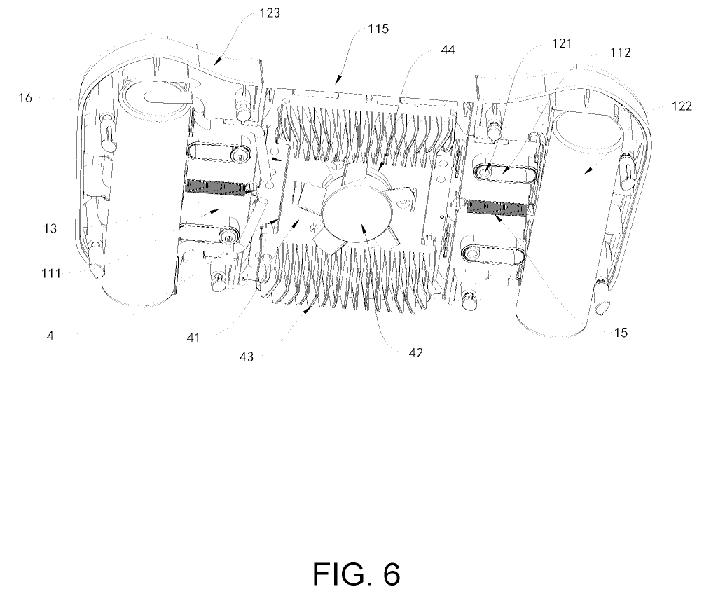

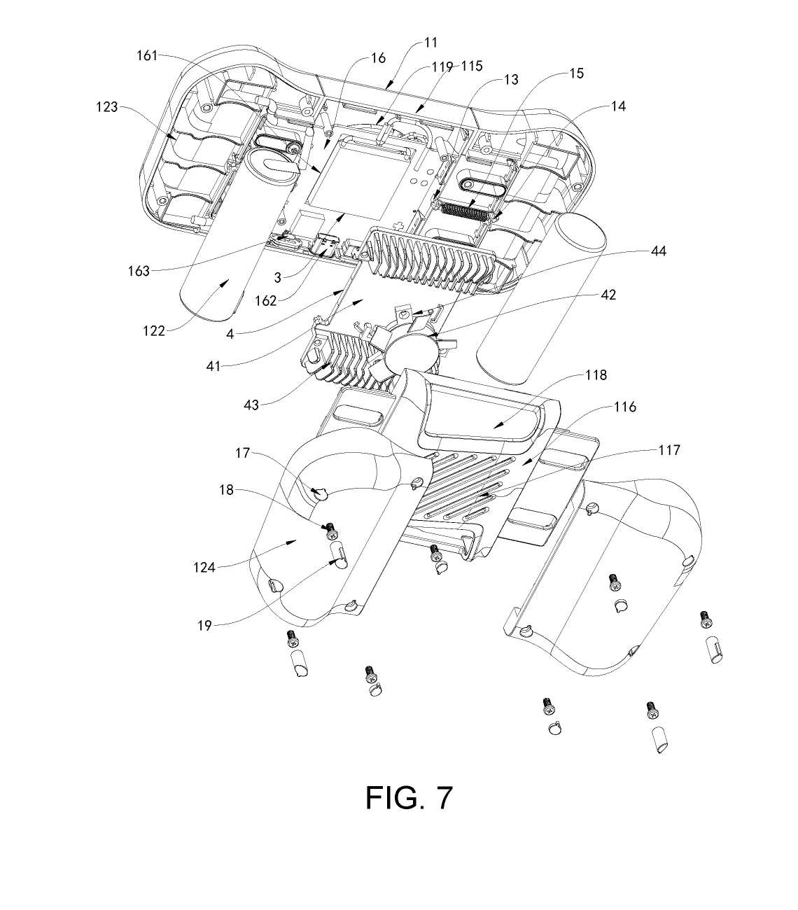

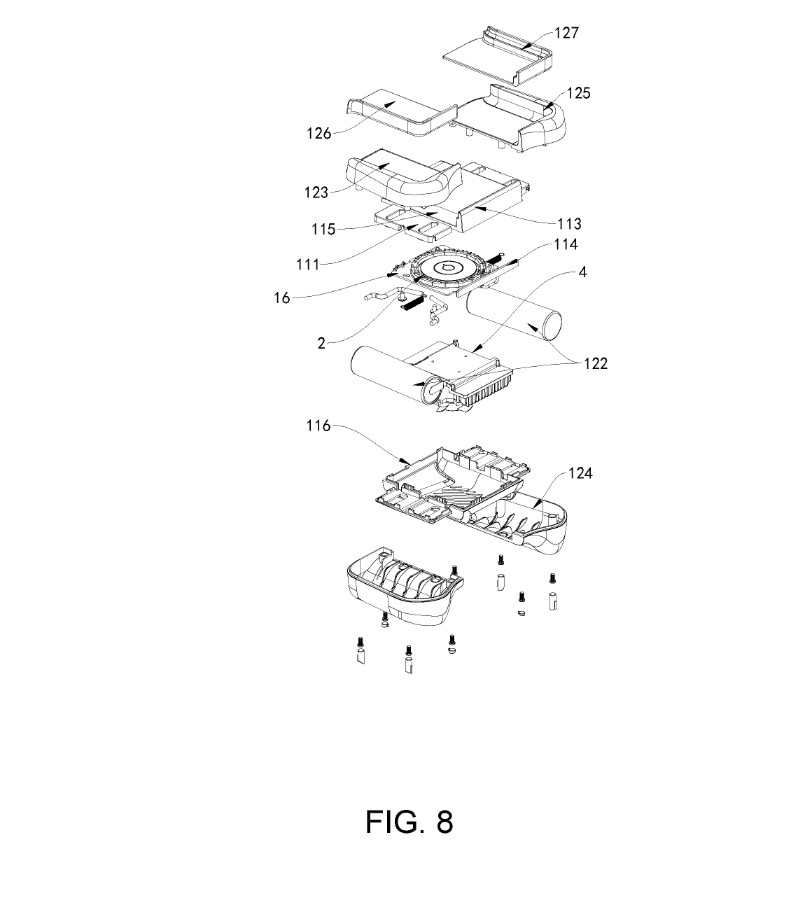

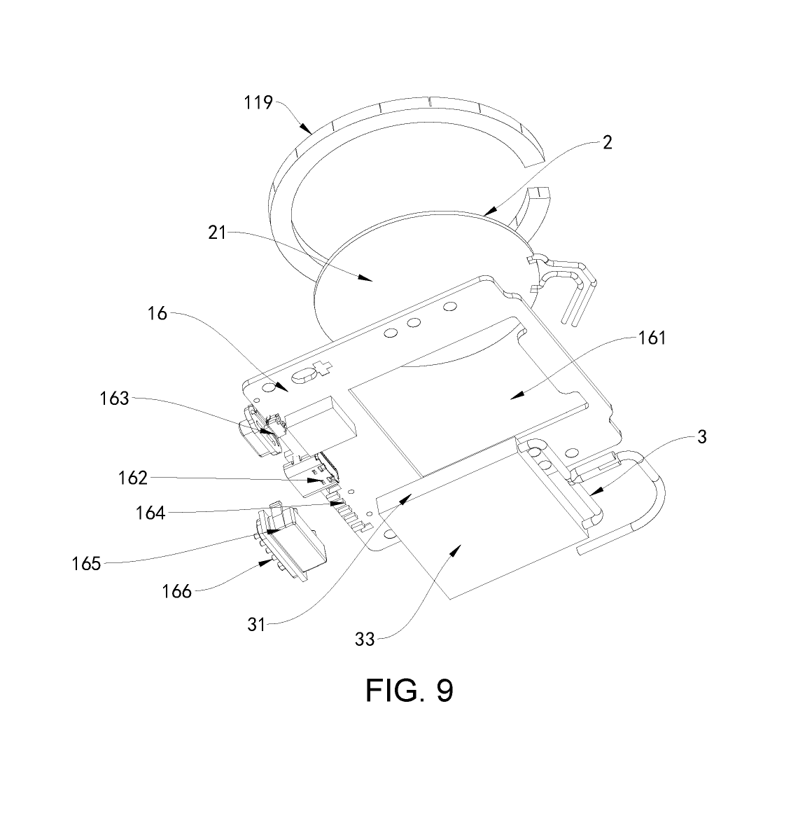

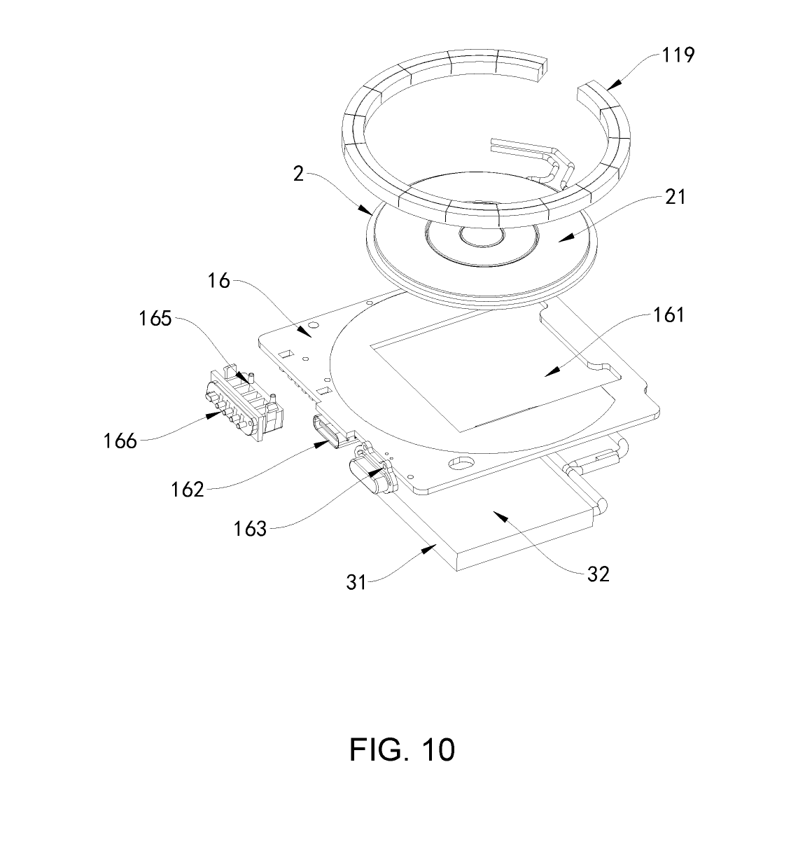

As shown in FIGS. 1–10, a multi-functional intelligent game controller with heat dissipation and wireless charging according to one embodiment of the present discloses comprises:

a controller body 1 having a clamping structure for holding a mobile terminal;

a wireless charging module 2 disposed inside the controller body 1 and configured to wirelessly charge the mobile terminal;

a thermoelectric cooling module 3 disposed inside the controller body 1 and configured to cool the mobile terminal;

a heat dissipation module 4 disposed on one side of the thermoelectric cooling module 3 to timely dissipate heat generated by the thermoelectric cooling module 3 and ensure continuous and efficient operation of the thermoelectric cooling module 3.

A battery 122 and a circuit board 16 are disposed inside the controller body 1, and the battery 122 supplies operating power to the wireless charging module 2, the thermoelectric cooling module 3, and the heat dissipation module 4 via the circuit board 16.

The product integrates three functions: wireless charging, thermoelectric cooling, and heat dissipation.

When a user plays games on a mobile phone, the product can continuously replenish power to the mobile phone via the wireless charging module 2 and actively cool the mobile phone via the thermoelectric cooling module 3, effectively preventing problems such as high-temperature throttling, lagging, and reduced frame rates caused by prolonged gaming, thereby enhancing gaming experience.

Meanwhile, the clamping structure can stably fix the mobile phone, freeing the user’s hands and realizing the comprehensive functions of charging, playing, and heat dissipation simultaneously, solving the pain point of single function in traditional mobile phone holders.

As shown in FIGS. 1–10, in some embodiments, the clamping structure comprises a main body portion 11 and a grip portion 12 movably connected to at least one end of the main body portion 11, wherein the grip portion 12 is movable relative to the main body portion 11 to adjust the clamping width.

Specifically, the clamping structure comprises the main body portion 11 and the grip portion 12 movably connected to at least one end of the main body portion 11.

The grip portion 12 can move linearly relative to the main body portion 11.

By adjusting the relative distance between the grip portion 12 and the main body portion 11, the overall width of the clamping structure is changed, thereby adapting to mobile terminals of different sizes.

When the grip portion 12 is pulled outward, the clamping width increases to accommodate larger mobile phones; when the grip portion 12 is retracted inward, the clamping width decreases to clamp smaller mobile phones.

The movable grip portion 12 enables the product to be compatible with mobile terminals of different sizes on the market, including mobile phones of various sizes, without requiring separate grip portions 12 for different phone models, improving the versatility and applicability of the product.

Users can install a mobile phone simply by stretching the grip portion 12, making operation convenient.

As shown in FIGS. 1–10, in some embodiments, at least one side of the main body portion 11 is extended with a connecting plate 111, and the connecting plate 111 is formed with a guide hole 112 extending along its length; the grip portion 12 is internally provided with a guide post 121 slidably engaged with the guide hole 112;

the main body portion 11 is internally provided with a first connecting portion 13, and the grip portion 12 is internally provided with a second connecting portion 14; the connecting plate 111 is internally provided with an elastic member 15, two ends of the elastic member 15 being respectively connected to the first connecting portion 13 and the second connecting portion 14 to provide a restoring force to the grip portion 12 toward the main body portion 11;

the grip portion 12 is internally provided with a battery 122, the main body portion 11 is internally provided with a circuit board 16, and the battery 122 is electrically connected to the circuit board 16.

The connecting plate 111 is movably sleeved between the front shell 123 and the bottom shell 124 of the grip portion 12.

When the grip portion 12 is pulled, the connecting plate 111 slides relative to the grip portion 12, and the guide post 121 slides within the guide hole 112 to provide guidance and limitation for the movement of the grip portion 12.

At least one side of the main body portion 11 is extended with the connecting plate 111, which is formed with the guide hole 112 extending along its length.

The grip portion 12 is internally provided with the guide post 121 slidably engaged with the guide hole 112.

The guide post 121 is embedded in the guide hole 112 and slides along the guide hole 112, providing precise guidance and limitation for the movement of the grip portion 12 and preventing deflection of the grip portion 12 during movement.

The main body portion 11 is internally provided with the first connecting portion 13, and the grip portion 12 is internally provided with the second connecting portion 14.

The connecting plate 111 is internally provided with the elastic member 15 (usually a spring), two ends of which are respectively connected to the first connecting portion 13 (e.g., a hook) and the second connecting portion 14 (e.g., a hook).

When the grip portion 12 is pulled outward, the elastic member 15 is stretched and stores elastic potential energy; when the grip portion 12 is released, the elastic member 15 contracts and resets, driving the grip portion 12 to move toward the main body portion 11, thereby clamping the mobile phone.

The grip portion 12 is internally provided with the battery 122, and the main body portion 11 is internally provided with the circuit board 16.

The battery 122 is electrically connected to the circuit board 16 to supply power to the entire product.

The matching structure of the guide hole 112 and the guide post 121 ensures movement stability of the grip portion 12 during extension and retraction, preventing uneven stress on the mobile phone caused by clamping deflection.

The elastic member 15 realizes automatic reset and clamping of the grip portion 12.

Users only need to pull out the grip portion 12 to place a mobile phone, and the grip portion 12 automatically clamps after release, making operation simple and labor-saving.

Meanwhile, the built-in battery 122 in the grip portion 12 enables the product to function as a portable power bank, independently supplying power to the wireless charging module 2, the thermoelectric cooling module 3, and the heat dissipation module 4 without an external power source, ensuring that the product can simultaneously realize wireless charging and active heat dissipation in outdoor or mobile scenarios, truly achieving a full-featured experience of “charging, playing, and dissipating heat simultaneously” and greatly improving portability and flexibility of application scenarios.

As shown in FIGS. 1–10, in some embodiments, the controller further comprises a temperature detection unit and a control unit, wherein the temperature detection unit is configured to detect temperature, and the control unit is electrically connected to the wireless charging module 2, the thermoelectric cooling module 3, and the temperature detection unit, respectively;

the control unit is configured to adjust the operating power of the thermoelectric cooling module 3 according to a detection result of the temperature detection unit;

the temperature detection unit and the control unit are integrally disposed on the circuit board 16.

The product further comprises the temperature detection unit and the control unit.

Specifically, the temperature detection unit is a temperature sensor disposed inside the main body portion 11, electrically connected to the circuit board 16 (e.g., soldered on the circuit board 16 or connected to the circuit board 16 via a wire), and configured to detect the temperature of the wireless charging module 2 or the mobile terminal in real time.

Specifically, the control unit is a microcontroller (MCU) integrally disposed on the circuit board 16, electrically connected to the wireless charging module 2, the thermoelectric cooling module 3, and the temperature sensor, respectively.

The microcontroller has a preset temperature threshold built-in, and dynamically adjusts the operating power of the thermoelectric cooling module 3 by reading temperature signals collected by the temperature sensor.

When the temperature detected by the temperature sensor is lower than a first preset threshold, the microcontroller controls the thermoelectric cooling module 3 to operate at low power or stop operating; when the temperature detected by the temperature sensor rises to a second preset threshold, the microcontroller controls the thermoelectric cooling module 3 to operate at high power, realizing on-demand cooling.

The temperature sensor and the microcontroller are integrally disposed on the circuit board 16, forming a highly integrated control core.

By collecting temperature signals in real time via the temperature sensor, the microcontroller precisely controls the operating state of the thermoelectric cooling module 3 according to a preset temperature control strategy, realizing intelligent start/stop and power adjustment of the thermoelectric cooling module 3 and avoiding energy waste caused by long-term full-load operation of the thermoelectric cooling module 3.

When the temperature of the mobile phone is low, the cooling module operates at low power or stops to save power; when the temperature of the mobile phone rises, the cooling module automatically starts and enhances cooling effect, accurately addressing overheating issues.

Such a microcontroller-based intelligent temperature control strategy not only guarantees the heat dissipation effect of the mobile phone but also optimizes overall power consumption and extends the battery life of the product.

As shown in FIGS. 1–10, in some embodiments, a top portion of the main body portion 11 is provided with a limiting flange 113 along an edge thereof, and one side of the limiting flange 113 is provided with a first flexible pad 114; the grip portion 12 comprises a front shell 123 and a bottom shell 124 fastened to each other, a top portion of the front shell 123 is formed with an L-shaped limiting arm 125, and an inner side of the limiting arm 125 and the top portion of the front shell 123 are jointly provided with a second flexible pad 126; the limiting arm 125 and the limiting flange 113 together define a U-shaped limiting space for accommodating the mobile terminal.

The top portion of the main body portion 11 is provided with the limiting flange 113 along its edge, and one side of the limiting flange 113 is provided with the first flexible pad 114 for contacting the side of the mobile phone to provide buffering and positioning.

The grip portion 12 comprises the front shell 123 and the bottom shell 124 fastened to each other.

The top portion of the front shell 123 is formed with the L-shaped limiting arm 125, and an inner side of the limiting arm 125 and the top portion of the front shell 123 are jointly provided with the second flexible pad 126.

The limiting arm 125 and the limiting flange 113 together define the U-shaped limiting space.

When a mobile phone is placed therein, the bottom and left/right ends of the mobile phone are limited by the limiting flange 113 and the limiting arm 125, respectively; the back of the mobile phone contacts the top portion of the main body portion 11, and the left/right ends of the mobile phone are supported by the second flexible pad 126.

The U-shaped limiting space formed by the limiting flange 113 and the L-shaped limiting arm 125 can position and constrain the mobile phone from multiple directions, ensuring that the mobile phone does not shake or shift after clamping.

The first flexible pad 114 (usually made of TPE) and the second flexible pad 126 (usually made of TPE) provide buffering when contacting the mobile phone, preventing scratches on the mobile phone surface, increasing friction, and improving clamping stability.

The L-shaped limiting arm 125 can provide limitation from both the top and side of the mobile phone, enhancing clamping firmness.

As shown in FIGS. 1–10, in some embodiments, a top surface of the main body portion 11 is higher than a top surface of the front shell 123, such that a back surface of the mobile terminal is attached to the top surface of the main body portion 11 and maintains a gap with the top surface of the front shell 123 after assembly;

the second flexible pad 126 is further provided with a supporting portion 127 at a position corresponding to an inner side of the limiting arm 125, and a height of the supporting portion 127 matches a protruding height of the top surface of the main body portion 11 to support the mobile terminal.

The top surface of the main body portion 11 is higher than the top surface of the front shell 123, so that after assembly of the mobile phone, the back surface of the mobile phone is directly attached to the top surface of the main body portion 11, while a certain gap is maintained between the back surface of the mobile phone and the top surface of the front shell 123, forming a heat insulation space.

The second flexible pad 126 is further provided with the supporting portion 127 (usually made of TPE) at a position corresponding to the inner side of the limiting arm 125, and the height of the supporting portion 127 matches the protruding height of the top surface of the main body portion 11.

After the mobile phone is placed, the two ends and bottom edge of the mobile phone are supported by the supporting portion 127, keeping the mobile phone horizontal.

The design where the top surface of the main body portion 11 is higher than the top surface of the front shell 123 allows heat of the mobile phone to be mainly transferred to the thermoelectric cooling module 3 via the main body portion 11 for heat dissipation, while the grip portion 12 does not directly contact the mobile phone.

The intermediate heat insulation gap effectively blocks heat conduction to the grip portion 12, so that the user does not feel heat from the mobile phone when holding the grip portion 12, greatly improving grip comfort.

The supporting portion 127 supports the mobile phone from the bottom, forming a stable three-point support structure together with the top surface of the main body portion 11 and the limiting arm 125, preventing shaking or sinking of the mobile phone during gaming due to user operations.

As shown in FIGS. 1–10, in some embodiments, the wireless charging module 2 comprises a wireless charging coil 21 disposed inside the main body portion 11 and a charging control circuit electrically connected to the wireless charging coil 21;

the thermoelectric cooling module 3 comprises a thermoelectric cooling chip 31 disposed inside the main body portion 11, the thermoelectric cooling chip 31 having opposite cooling and heating surfaces 32, 33, wherein the cooling surface 32 is disposed toward the mobile terminal, and the heating surface 33 is thermally connected to the heat dissipation module 4.

The wireless charging coil 21 is manufactured using a flexible printed circuit (FPC) process, comprising spiral copper foil traces and an insulating layer covering the surface thereof, presenting an overall sheet-like structure.

This structure not only gives the wireless charging coil 21 a relatively thin thickness for easy integration inside the main body portion 11 but also allows its flat surface to closely attach to the cooling surface 32 of the thermoelectric cooling chip 31, achieving efficient heat conduction.

The charging control circuit is integrated on the circuit board 16, comprising a wireless charging control chip and a power management chip.

The wireless charging control chip adopts a control scheme compliant with the Qi wireless charging standard, responsible for driving the wireless charging coil 21 to generate an alternating magnetic field to realize wireless charging of the mobile terminal, and has safety functions such as foreign object detection, overcurrent protection, and overtemperature protection.

The power management chip is connected between the charging interface 162 (usually a Type-C interface) and the built-in battery 122, and has a power path management function: when an external power source is connected to the charging interface 162, the power management chip preferentially delivers the external power directly to the wireless charging module 2, the thermoelectric cooling module 3, and the heat dissipation module 4, ensuring stable operation of each module under external power supply, while allocating surplus electric energy to charge the built-in battery 122; when no external power source is connected, the power management chip switches to a battery 122 power supply mode, where the built-in battery 122 supplies power to each module.

The operating state of the charging control circuit is uniformly coordinated and controlled by the microcontroller integrated on the circuit board 16.

The thermoelectric cooling module 3 comprises the thermoelectric cooling chip 31 disposed inside the main body portion 11.

The thermoelectric cooling chip 31 has opposite cooling and heating surfaces 32, 33, wherein the cooling surface 32 is disposed toward the mobile terminal and directly or indirectly contacts the back of the mobile phone to absorb heat; the heating surface 33 is attached to the middle portion of the heat conduction bracket 41 in the heat dissipation module 4 to conduct absorbed heat to the heat dissipation bracket for dissipation.

The wireless charging control chip adopts a Qi standard scheme, ensuring good compatibility with mainstream wireless-charging-enabled mobile phones on the market, and has complete protection functions to guarantee charging safety.

The power path management function of the power management chip realizes intelligent switching between external power priority supply and battery 122 charging: when an external power source is connected, each functional module is directly powered by the external power source, ensuring stable performance of the product without being limited by the battery 122 power level in high-power scenarios (simultaneous wireless charging and active heat dissipation), while replenishing power to the battery 122; when disconnected from the external power source, the product automatically switches to battery 122 power supply, ensuring portable use.

Such a dual-mode power supply design allows the product to be used both as a desktop wireless charging radiator and as a portable power bank cooling controller, expanding application scenarios.

The unified coordinated control of the microcontroller ensures collaborative operation of the wireless charging, active heat dissipation, and power management functional modules, achieving overall optimal performance.

The wireless charging coil 21 and the thermoelectric cooling chip 31 are integrated in the same main body portion 11, enabling the product to have both charging and heat dissipation functions without spatial interference.

The cooling surface 32 of the thermoelectric cooling chip 31 directly faces the mobile phone, efficiently absorbing heat generated by the mobile phone and realizing active cooling; the heating surface 33 is connected to the heat dissipation module 4, ensuring rapid heat export and sustained cooling capacity of the thermoelectric cooling chip 31.

As shown in FIGS. 1–10, in some embodiments, the main body portion 11 comprises an upper shell 115 and a lower shell 116, a central bottom portion of the lower shell 116 is formed with an air inlet 117, and front and rear sides of the bottom portion of the lower shell 116 are respectively formed with air outlets 118;

a plurality of magnets 119 are disposed inside the upper shell 115, and the plurality of magnets 119 are arranged at intervals around the wireless charging coil 21 and closely attached to an inner wall of the upper shell 115;

the circuit board 16 is formed with an escape hole 161, and the cooling surface 32 of the thermoelectric cooling chip 31 passes through the escape hole 161 and is attached to a bottom portion of the wireless charging coil 21.

The main body portion 11 is formed by fastening the upper shell 115 and the lower shell 116.

The central bottom portion of the lower shell 116 is formed with the air inlet 117, which consists of a plurality of arrayed elongated holes; the front and rear sides of the bottom portion of the lower shell 116 are respectively formed with the air outlets 118, which are strip-shaped openings extending along sides of the lower shell 116, extending from the front or rear side of the lower shell 116 to the bottom portion of the lower shell 116 and located on one side of the air inlet 117 array, forming a complete air circulation channel; the air inlet 117 and the air outlets 118 together form an air circulation path.

The plurality of magnets 119 are disposed inside the upper shell 115, arranged at intervals around the wireless charging coil 21 and closely attached to the inner wall of the upper shell 115, for cooperating with magnetic attraction members inside the mobile phone to realize automatic alignment and adsorption.

The circuit board 16 is formed with the escape hole 161, and the cooling surface 32 of the thermoelectric cooling chip 31 passes through the escape hole 161 and is attached to the bottom portion of the wireless charging coil 21, allowing the cooling chip to simultaneously cool the mobile phone and the wireless charging coil 21, effectively solving the overheating problem during wireless charging.

The layout of the air inlet 117 and the air outlets 118 forms a complete air convection path.

External cold air enters from the central bottom air inlet 117, flows through the heat dissipation assembly, and exits from the front and rear air outlets 118, realizing efficient air circulation and heat dissipation.

The plurality of magnets 119 are arranged at intervals around the wireless charging coil 21 and closely attached to the inner wall of the upper shell 115, forming a magnetic attraction positioning structure.

When a mobile phone approaches, automatic adsorption and alignment are achieved, ensuring precise alignment between the wireless charging coil 21 and the mobile phone receiving coil and improving charging efficiency.

The cooling surface 32 of the thermoelectric cooling chip 31 passes through the escape hole 161 and attaches to the bottom portion of the wireless charging coil 21, allowing the cooling chip to simultaneously remove heat from the mobile phone and the wireless charging coil 21.

As shown in FIGS. 1–10, in some embodiments, the heat dissipation module 4 comprises a heat conduction bracket 41 and a fan 42, a middle portion of the heat conduction bracket 41 is attached to the heating surface 33 of the thermoelectric cooling chip 31, two ends of the heat conduction bracket 41 extend downward and are provided with heat dissipation fin groups 43, and the two heat dissipation fin groups 43 respectively extend to the two air outlets 118; the fan 42 is disposed between the middle portion of the heat conduction bracket 41 and the air inlet 117.

The fan 42 is fixedly mounted between the middle portion of the heat conduction bracket 41 and the air inlet 117 via a fan bracket 44.

The fan bracket 44 suspends and supports the fan 42, maintaining a certain airflow gap between the fan 42 and the heat conduction bracket 41 to ensure that the fan 42 can effectively draw in cold air and flow it through the heat conduction bracket 41 and the heat dissipation fin groups 43 during operation.

The heat dissipation module 4 comprises the heat conduction bracket 41 and the fan 42.

The middle portion of the heat conduction bracket 41 is a flat plate-like structure attached to the heating surface 33 of the thermoelectric cooling chip 31, ensuring full contact and minimal thermal resistance therebetween, and rapidly conducting heat generated by the thermoelectric cooling chip 31 to the heat conduction bracket 41.

Two ends of the heat conduction bracket 41 extend downward and are provided with the heat dissipation fin groups 43, which respectively extend to the two air outlets 118.

The multi-fin structure significantly increases the contact area with air.

The fan 42 is disposed between the middle portion of the heat conduction bracket 41 and the air inlet 117.

During operation, the fan 42 draws external cold air in through the air inlet 117; the cold air flows through the heat dissipation fin groups 43 to take away heat, and hot air is discharged through the air outlets 118, forming a complete forced convection heat dissipation cycle.

The flat plate-like middle portion of the heat conduction bracket 41 can form close contact with the heating surface 33 of the thermoelectric cooling chip 31, featuring large contact area and uniform attachment, effectively reducing contact thermal resistance and enabling rapid and efficient heat transfer from the thermoelectric cooling chip 31 to the heat conduction bracket 41, avoiding heat accumulation at the cooling chip.

The heat conduction bracket 41 rapidly transfers heat to the heat dissipation fin groups 43 at both ends, and the large-area structure of the heat dissipation fin groups 43 significantly improves heat dissipation efficiency.

The fan 42 (high-speed silent fan) is located between the air inlet 117 and the heat conduction bracket 41, forming forced convection heat dissipation and accelerating hot air discharge.

The two heat dissipation fin groups 43 respectively extend to the front and rear air outlets 118, allowing simultaneous heat discharge from two directions and avoiding heat accumulation inside the shell, ensuring that the thermoelectric cooling chip 31 remains in an efficient operating state and thus sustaining cooling capacity for the mobile phone.

In some embodiments, screw mounting holes 17 are formed on both the bottom shell 124 of the grip portion 12 and the lower shell 116 of the main body portion 11 for inserting screws 18 to lock the front shell 123 and the upper shell 115.

Hole plugs 19 for sealing are disposed in the screw mounting holes 17.

The hole plugs 19 (usually made of rubber) are in interference fit with the screw mounting holes 17 to cover the screws 18 and maintain a neat product appearance.

As shown in FIGS. 1–10, in some embodiments, a charging interface 162, a switch button 163, and an indicator light 164 are integrated on the circuit board 16; the circuit board 16 is further provided with a light shield 165 cooperating with the indicator light 164, and one end of the light shield 165 is provided with a light guide post 166;

the upper shell 115 is formed with through holes 1151 at corresponding positions for exposing the charging interface 162, the switch button 163, and the light guide post 166.

The charging interface 162, the switch button 163, and the indicator light 164 are integrated on the circuit board 16.

The charging interface 162 is used for connecting an external power source and is electrically connected to the power management chip on the circuit board 16.

When an external power source is connected, the power management chip automatically recognizes and preferentially delivers the external power directly to the wireless charging module 2, the thermoelectric cooling module 3, and the heat dissipation module 4, while charging the built-in battery 122; when no external power source is connected, the power management chip automatically switches to the battery 122 power supply mode.

The switch button 163 is electrically connected to the microcontroller on the circuit board 16 for inputting control signals to the microcontroller to realize product on/off or function switching.

The indicator light 164 is electrically connected to the microcontroller on the circuit board 16, and its on/off state is controlled by the microcontroller to indicate the operating state, charging state, and battery 122 power level of the product.

The circuit board 16 is further provided with the light shield 165 cooperating with the indicator light 164, and one end of the light shield 165 is provided with the light guide post 166.

The light shield 165 is used to block stray light emitted by the indicator light 164, and the light guide post 166 guides light from the indicator light 164 to the through hole 1151 of the upper shell 115.

The upper shell 115 is formed with the through holes 1151 at corresponding positions for exposing the charging interface 162, the switch button 163, and the light guide post 166, allowing users to perform plugging and pressing operations and observe the state of the indicator light 164 through the through holes 1151.

Based on the power path management function of the power management chip, the charging interface 162 enables the product to have two power supply modes: when connected to an external power source, each functional module is directly powered by the external power source, ensuring stable product performance without being limited by the battery 122 power level in high-power scenarios where wireless charging and active heat dissipation operate simultaneously, while replenishing power to the built-in battery 122; when disconnected from the external power source, the product is powered by the built-in battery 122, ensuring portable use.

Intelligent switching between the two modes requires no user intervention and is convenient to operate.

The switch button 163 facilitates one-key user operation and simplifies the use process; the indicator light 164 guides light to the outer surface of the upper shell 115 via the light guide post 166, allowing users to intuitively learn information such as the charging state, operating state, and battery 122 power level of the product.

The light shield 165 prevents internal scattering of light from the indicator light 164, ensuring clear and concentrated indication light and improving user interaction experience.

Reasonable layout of each functional interface and switch button 163 on the upper shell 115 facilitates user operation while maintaining a neat and attractive product appearance.

In summary, the present discloses adapts to mobile phones of different sizes via the grip portion 12 movable relative to the main body portion 11; the guide hole 112 and the guide post 121 ensure stable extension and retraction, and the elastic member 15 achieves automatic reset and clamping, enabling convenient operation.

The top surface of the main body portion 11 is higher than the top surface of the grip portion 12 to form a heat insulation gap.

Cooperating with the limiting flange 113, the L-shaped limiting arm 125, and the supporting portion 127 on the second flexible pad 126, the controller stably clamps the mobile phone while effectively blocking heat conduction to the grip portion 12, improving grip comfort.

The controller integrates wireless charging, thermoelectric cooling, and heat dissipation functions.

A temperature sensor cooperates with a microcontroller to automatically adjust the power of the thermoelectric cooling chip 31 according to temperature, realizing on-demand cooling.

Combined with a power management chip, the controller intelligently switches between external power priority supply and battery 122 charging, ensuring stable operation in high-power scenarios while maintaining portability, thereby comprehensively optimizing the user’s gaming experience.

Finally, it should be noted that the above descriptions are only preferred embodiments of the present discloses and are not intended to limit the present discloses.

Although the present discloses has been described in detail with reference to the foregoing embodiments, those skilled in the art can still modify the technical solutions described in the foregoing embodiments or equivalently replace some of the technical features.

Any modifications, equivalent replacements, improvements, etc. made within the spirit and principles of the present discloses shall be included in the protection scope of the present discloses.

nt discloses.

1. A multi-functional intelligent game controller with heat dissipation and wireless charging, comprising:
a controller body having a clamping structure for holding a mobile terminal;
a wireless charging module disposed inside the controller body and configured to wirelessly charge the mobile terminal;
a thermoelectric cooling module disposed inside the controller body and configured to cool the mobile terminal;
a heat dissipation module disposed on one side of the thermoelectric cooling module and configured to dissipate heat generated by the thermoelectric cooling module.

2. The multi-functional intelligent game controller with heat dissipation and wireless charging according to claim 1, wherein the clamping structure comprises a main body portion and a grip portion movably connected to at least one end of the main body portion, and the grip portion is movable relative to the main body portion to adjust the clamping width.

3. The multi-functional intelligent game controller with heat dissipation and wireless charging according to claim 2, wherein at least one side of the main body portion is extended with a connecting plate, and the connecting plate is formed with a guide hole extending along its length.

4. The multi-functional intelligent game controller with heat dissipation and wireless charging according to claim 3, wherein the grip portion is internally provided with a guide post slidably engaged with the guide hole.

5. The multi-functional intelligent game controller with heat dissipation and wireless charging according to claim 2, wherein the main body portion is internally provided with a first connecting portion, and the grip portion is internally provided with a second connecting portion.

6. The multi-functional intelligent game controller with heat dissipation and wireless charging according to claim 5, wherein the connecting plate is internally provided with an elastic member, two ends of the elastic member being respectively connected to the first connecting portion and the second connecting portion to provide a restoring force to the grip portion toward the main body portion.

7. The multi-functional intelligent game controller with heat dissipation and wireless charging according to claim 2, wherein the grip portion is internally provided with a battery, the main body portion is internally provided with a circuit board, and the battery is electrically connected to the circuit board.

8. The multi-functional intelligent game controller with heat dissipation and wireless charging according to claim 1, further comprising a temperature detection unit and a control unit, wherein the temperature detection unit is configured to detect temperature, and the control unit is electrically connected to the wireless charging module, the thermoelectric cooling module, and the temperature detection unit, respectively;
the control unit is configured to adjust the operating power of the thermoelectric cooling module according to a detection result of the temperature detection unit;
the temperature detection unit and the control unit are integrally disposed on the circuit board.

9. The multi-functional intelligent game controller with heat dissipation and wireless charging according to claim 2, wherein a top portion of the main body portion is provided with a limiting flange along an edge thereof, and one side of the limiting flange is provided with a first flexible pad; the grip portion comprises a front shell and a bottom shell fastened to each other, a top portion of the front shell is formed with an L-shaped limiting arm, and an inner side of the limiting arm and the top portion of the front shell are jointly provided with a second flexible pad.

10. The multi-functional intelligent game controller with heat dissipation and wireless charging according to claim 9, wherein the limiting arm and the limiting flange together define a U-shaped limiting space for accommodating the mobile terminal.

11. The multi-functional intelligent game controller with heat dissipation and wireless charging according to claim 9, wherein a top surface of the main body portion is higher than a top surface of the front shell, such that a back surface of the mobile terminal is attached to the top surface of the main body portion and maintains a gap with the top surface of the front shell after assembly.

12. The multi-functional intelligent game controller with heat dissipation and wireless charging according to claim 9, wherein the second flexible pad is further provided with a supporting portion at a position corresponding to an inner side of the limiting arm, and a height of the supporting portion matches a protruding height of the top surface of the main body portion to support the mobile terminal.

13. The multi-functional intelligent game controller with heat dissipation and wireless charging according to claim 2, wherein the wireless charging module comprises a wireless charging coil disposed inside the main body portion and a charging control circuit electrically connected to the wireless charging coil;
the thermoelectric cooling module comprises a thermoelectric cooling chip disposed inside the main body portion, the thermoelectric cooling chip having opposite cooling and heating surfaces, wherein the cooling surface is disposed toward the mobile terminal, and the heating surface is thermally connected to the heat dissipation module.

14. The multi-functional intelligent game controller with heat dissipation and wireless charging according to claim 13, wherein the main body portion comprises an upper shell and a lower shell, a central bottom portion of the lower shell is formed with an air inlet, and front and rear sides of the bottom portion of the lower shell are respectively formed with air outlets.

15. The multi-functional intelligent game controller with heat dissipation and wireless charging according to claim 14, wherein a plurality of magnets are disposed inside the upper shell, and the plurality of magnets are arranged at intervals around the wireless charging coil and closely attached to an inner wall of the upper shell.

16. The multi-functional intelligent game controller with heat dissipation and wireless charging according to claim 15, wherein the circuit board is formed with an escape hole, and the cooling surface of the thermoelectric cooling chip passes through the escape hole and is attached to a bottom portion of the wireless charging coil.

17. The multi-functional intelligent game controller with heat dissipation and wireless charging according to claim 14, wherein the heat dissipation module comprises a heat conduction bracket and a fan, a middle portion of the heat conduction bracket is attached to the heating surface of the thermoelectric cooling chip, two ends of the heat conduction bracket extend downward and are provided with heat dissipation fin groups, and the two heat dissipation fin groups respectively extend to the two air outlets.

18. The multi-functional intelligent game controller with heat dissipation and wireless charging according to claim 17, wherein the fan is disposed between the middle portion of the heat conduction bracket and the air inlet.

19. The multi-functional intelligent game controller with heat dissipation and wireless charging according to claim 7, wherein a charging interface, a switch button, and an indicator light are integrated on the circuit board; the circuit board is further provided with a light shield cooperating with the indicator light, and one end of the light shield is provided with a light guide post.

20. The multi-functional intelligent game controller with heat dissipation and wireless charging according to claim 19, wherein the upper shell is formed with through holes at corresponding positions for exposing the charging interface, the switch button, and the light guide post.
